(19) United States
(12) Patent Application Publication
(10) Pub. No.: US 2009/0015298 A1
(43) Pub. Date: Jan. 15, 2009

(54) Output buffer circuit

(75) Inventors: Norihiro Saitou, Kanagawa (JP); Katsumi Honma, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Electronics Corporation, Kawasaki (JP)

(21) Appl. No.: 12/155,910

(22) Filed: Jun. 11, 2008

(30) Foreign Application Priority Data
Jul. 10, 2007 (JP) 180606/2007

(51) Int. Cl. H03B 1/00

(52) U.S. Cl. 327/108

(57) ABSTRACT

In the case of a conventional output buffer circuit, it is difficult to adjust rising and falling times of a signal outputted from each of differential output terminals (OUTP/OUTN). Provided is an output buffer circuit including: a delay circuit including a first, second and third delay paths coupled to a first, second and third nodes, respectively, each of the first, second, and third delay paths performing time shifting transmission for the input signal, thereby extracting a first, second and third signals from the first, second and third nodes, respectively; a first output buffer coupled from the first node to drive an output terminal in response to the first signal; a second output buffer coupled from the second node to drive the output terminal in response to the second signal; and a third output buffer coupled from the third node to drive the output terminal in response to the third signal.

### BACKGROUND OF THE INVENTION

1. Field of the Invention

The present invention relates to an output buffer circuit, and more particularly, to an output buffer circuit having a delay circuit.

2. Description of the Related Art

There is a problem in that, along with an increase in transmission speed or transmission distance, a transmission line loss occurs to deteriorate a signal waveform. An output buffer circuit for correcting the deteriorated signal waveform is disclosed in JP 2007-60073 A.

FIG. 9 shows an output buffer circuit 90 described in JP 2007-60073 A. In the output buffer circuit 90, a main buffer B91 receives, through a prebuffer 92, data signals differentially inputted to differential input terminals (INP/INN). A delay circuit 93 delays the received data signals and outputs the delayed data signal to a selection circuit 94. The selection circuit 94 selects one of a group including the signals outputted from the delay circuit 93 and a group including the data signals from differential input terminals (INP/INN) and outputs the selected group (signals) to a main buffer B95. The main buffer B95 receives the signals outputted from the selection circuit 94. A non-inverted output terminal of the main buffer B91 and an inverted output terminal of the main buffer B95 are coupled in common to a non-inverted output terminal OUTP. An inverted output terminal of the main buffer B91 and a normal terminal of the main buffer B95 are coupled in common to an inverted output terminal OUTN.

Hereinafter, the operation of the output buffer circuit 90 in the case of emphasis setting and the operation thereof in the case of non-emphasis setting are described with reference to FIGS. 9 to 11. FIG. 10 shows waveforms at respective sections between the non-inverted input terminal INP of the differential input terminals (INP/INN) and the non-inverted output terminal OUTP of the differential output terminals (OUTP/OUTN) in the case of emphasis setting. FIG. 11 shows waveforms at the respective sections between the non-inverted input terminal INP of the differential input terminals (INP/INN) and the non-inverted output terminal OUTP of the differential output terminals (OUTP/OUTN) in the case of non-emphasis setting. In the case of emphasis setting, the main buffer B91 receives, through the prebuffer 92, the data signals differentially inputted to the differential input terminals (INP/INN), and outputs the received data signals to the differential output terminals (OUTP/OUTN) (see “OUTPUT OF MAIN BUFFER B91 TO OUTP” of FIG. 10). The main buffer B95 receives the data signals which are differentially inputted to the differential input terminals (INP/INN) and delayed by the delay circuit 93, and outputs the received data signals to the differential output terminals (OUTP/OUTN) (see “OUTPUT OF MAIN BUFFER B95 TO OUTP” of FIG. 10). A composite signal of the signal outputted from the main buffer B91 and the signal outputted from the main buffer B95 is outputted from the non-inverted output terminal OUTP. Therefore, in the case of emphasis setting, the composite signal, that is, a signal whose amplitude at the time of a change in logic is emphasized is outputted as an output signal from the output buffer circuit 90 (see t3 to t18 of FIG. 10).

On the other hand, in the case of non-emphasis setting, the main buffer B91 receives, through the prebuffer 92, the data signals differentially inputted to the differential input terminals (INP/INN), and outputs the received data signals to the differential output terminals (OUTP/OUTN) (see “OUTPUT OF MAIN BUFFER B91 TO OUTP” of FIG. 11). The main buffer B95 receives the data signals through the selection circuit 94 and outputs the received data signals to the differential output terminals (OUTP/OUTN) (see “OUTPUT OF MAIN BUFFER B95 TO OUTP” of FIG. 11). Therefore, in the case of non-emphasis setting, a composite signal of the signal outputted from the main buffer B91 and the signal outputted from the main buffer B95 is outputted from the output buffer circuit 90.

As described above, the output buffer circuit 90 emphasizes the amplitude of the signal outputted from each of the differential output terminals (OUTP/OUTN) at the time of the change in logic, and outputs the signal whose amplitude is emphasized to a receiving side. Because the output buffer circuit 90 outputs the signal having such an output waveform to the receiving side, a deteriorated waveform of the signal to be inputted to the receiving side can be corrected.

An output buffer circuit having output resistors is disclosed in JP 2007-81608 A. The output resistors are provided between a power supply and an output pair of a differential circuit and variably controlled in conjunction with a pre-emphasis operation to adjust an output impedance. A semiconductor integrated circuit device having an output circuit is disclosed in JP 2004-327602 A. The output circuit includes a plurality of output MOSFETs coupled in parallel and an arbitrary MOSFET thereof is turned on to adjust a slew rate.

However, examples of deteriorated characteristics of a signal on a transmission line which cannot be corrected by processing such as emphasis processing include a rising characteristic and a falling characteristic of the signal. Parasitic capacitors are normally formed on the transmission line. In FIG. 9, the parasitic capacitors are expressed as capacitors “C” coupled between the differential output terminals (OUTP/OUTN) and a ground potential terminal. In FIG. 9, load resistors coupled to the differential output terminals (OUTP/OUTN) are expressed by resistors RL. The rising and falling characteristics of the signal are determined based on a time constant. The time constant of the output buffer circuit 90 shown in FIG. 9 is calculated by “C×RL”. When the time constant is large, the rising and falling characteristics of the signal are gradual. When the time constant is small, the rising and falling characteristics of the signal are rapid.

According to the conventional technologies, when emphasis is performed, the signal can be prevented from being deteriorated. However, the rising and falling times of the signal cannot be adjusted. Therefore, the conventional technologies have a problem in that the rising and falling times of the signal are significantly varied due to variations in parasitic capacitance of a transmission path in a state in which a semiconductor device is mounted.

### SUMMARY

According to one aspect of the prevent invention, an output buffer circuit includes: an input terminal receiving an input signal; a delay circuit coupled from the input terminal, the delay circuit having a plurality of delay elements to delay the input signal, the plurality of delay elements including: a first delay path coupled to a first node, the first delay path performing time shifting transmission for the input signal, thereby extracting a first signal from the first node; a second delay path coupled to a second node, the second delay path performing time shifting transmission longer than a delay time of the first delay path for the input signal, thereby extracting a second signal from the second node; and a third delay path coupled to a third node, the third delay path performing time shifting transmission longer than a delay time of the second delay path for the input signal, thereby extracting a third signal from the third node; an output terminal; a first output buffer coupled from the first node to drive the output terminal in response to the first signal, in which a path of the first delay path and the first output buffer is arranged and configured to perform a logically NON reversible function in one pass through the first delay path and the first output buffer via the first node; a second output buffer coupled from the second node to drive the output terminal in response to the second signal; and a third output buffer coupled from the third node to drive the output terminal in response to the third signal, in which a path of the third delay path and the third output buffer is arranged and configured to perform a logically reversible function in one pass through the third delay path and the third output buffer via the third node.

According to another aspect of the prevent invention, an output buffer circuit includes: an input terminal receiving an input signal; a delay circuit coupled from the input terminal, the delay circuit having a plurality of delay elements to delay the input signal, the plurality of delay elements including: a first delay path coupled to a first node, the first delay path performing time shifting transmission for the input signal, thereby extracting a first signal from the first node; a second delay path coupled to a second node, the second delay path performing time shifting transmission longer than a delay time of the first delay path for the input signal, thereby extracting a second signal from the second node; and a third delay path coupled to a third node, the third delay path performing time shifting transmission longer than a delay time of the second delay path for the input signal, thereby extracting a third signal from the third node; an output terminal; a select terminal receiving a select signal; a first multiplexing driver selectively coupled from one of the input terminal and the first node in response to the select signal to drive the output terminal in response to one of the input signal and the first signal, respectively, in which a path of the first delay path and the first multiplexing driver is arranged and configured to perform a logically NON reversible function in one pass through the first delay path and the first multiplexing driver via the first node, and a path of the input terminal and the first multiplexing driver is arranged and configured to perform a logically NON reversible function in one pass through the input terminal and the first multiplexing driver; a second multiplexing driver selectively coupled from one of the input terminal and the second node in response to the select signal to drive the output terminal in response to one of the input signal and the second signal, respectively; and a third multiplexing driver selectively coupled from one of the input terminal and the third node in response to the select signal to drive the output terminal in response to the one of input signal and the third signal, respectively, in which a path of the third delay path and the third multiplexing driver is arranged and configured to perform a logically reversible function in one pass through the third delay path and the third multiplexing driver via the third node, and a path of the input terminal and the third multiplexing driver is arranged and configured to perform a logically reversible function in one pass through the input terminal and the third multiplexing driver.

According to still another aspect of the prevent invention, in the output buffer circuit, the plurality of delay elements are coupled with each other in series to reflect a delay time of the signal inputted to the first output buffer in a delay time of the signal inputted to the second output buffer. Therefore, in the output buffer circuit according to the present invention, rising and falling times of a composite signal can be set based on a delay time determined by delay elements coupled between an input terminal of the first output buffer and an input terminal of the second output buffer.

According to the present invention, it is possible to provide an output buffer circuit capable of adjusting rising and falling times of an output signal outputted from an output buffer.

### BRIEF DESCRIPTION OF THE DRAWINGS

In the accompanying drawings:

FIG. 1 is a diagram showing an output buffer circuit 100 according to Embodiment 1 of the present invention;

FIG. 2 is a timing chart showing waveforms at respective sections of the output buffer circuit 100 according to Embodiment 1 of the present invention;

FIG. 3 is another timing chart showing waveforms at the respective sections of the output buffer circuit 100 according to Embodiment 1 of the present invention;

FIG. 4 is a diagram showing an output buffer circuit 200 according to Embodiment 2 of the present invention;

FIG. 5 is a diagram showing an output buffer circuit 300 according to Embodiment 3 of the present invention;

FIG. 6 is a timing chart showing waveforms at respective sections of the output buffer circuit 300 according to Embodiment 3 of the present invention;

FIG. 7 is another timing chart showing waveforms at the respective sections of the output buffer circuit 300 according to Embodiment 3 of the present invention;

FIG. 8 is a diagram showing an output buffer circuit 400 according to Embodiment 4 of the present invention;

FIG. 9 is a diagram showing an output buffer circuit 90 described in JP 2007-60073 A;

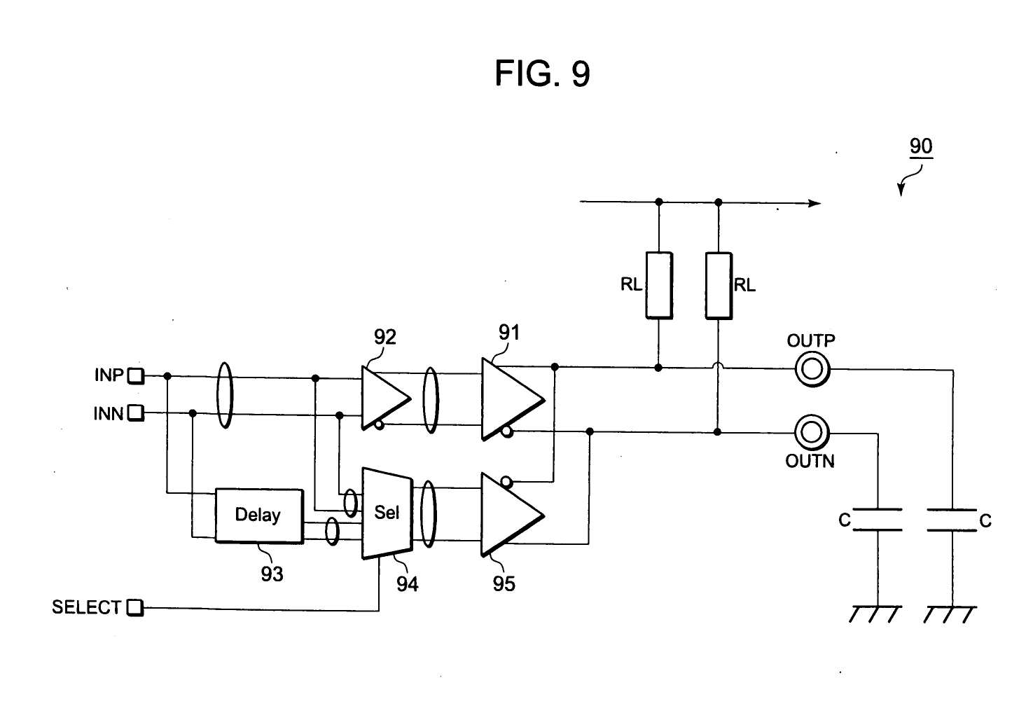

FIG. 10 is a timing chart showing waveforms at respective sections of the output buffer circuit 90 described in JP 2007-60073 A; and

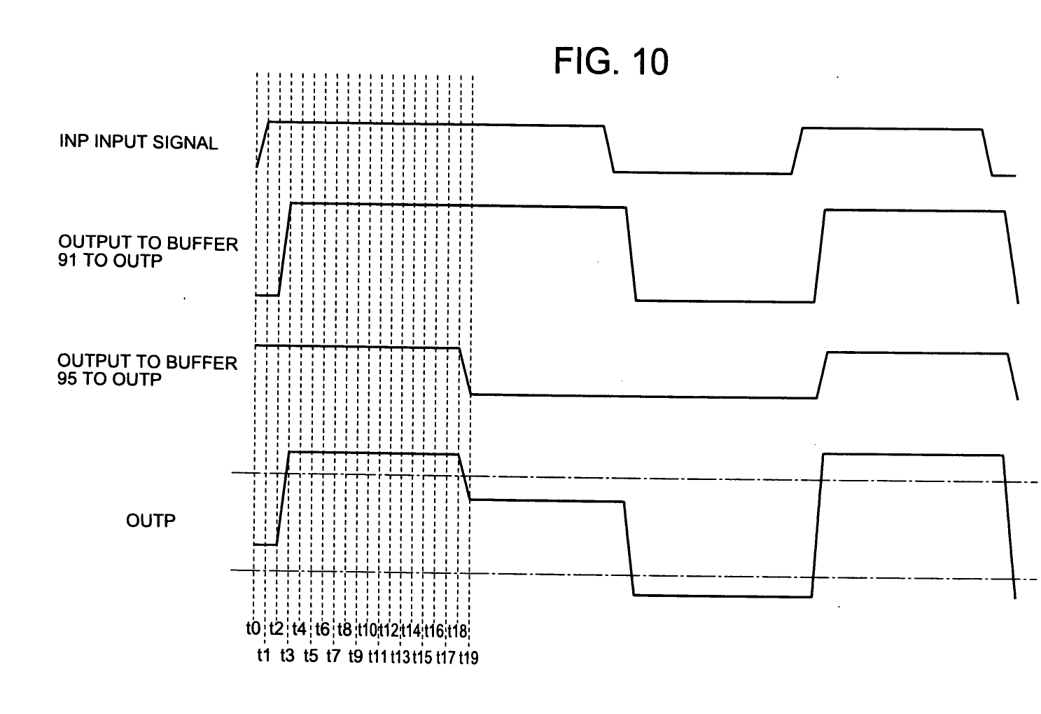

FIG. 11 is another timing chart showing waveforms at the respective sections of the output buffer circuit 90 described in JP 2007-60073 A.

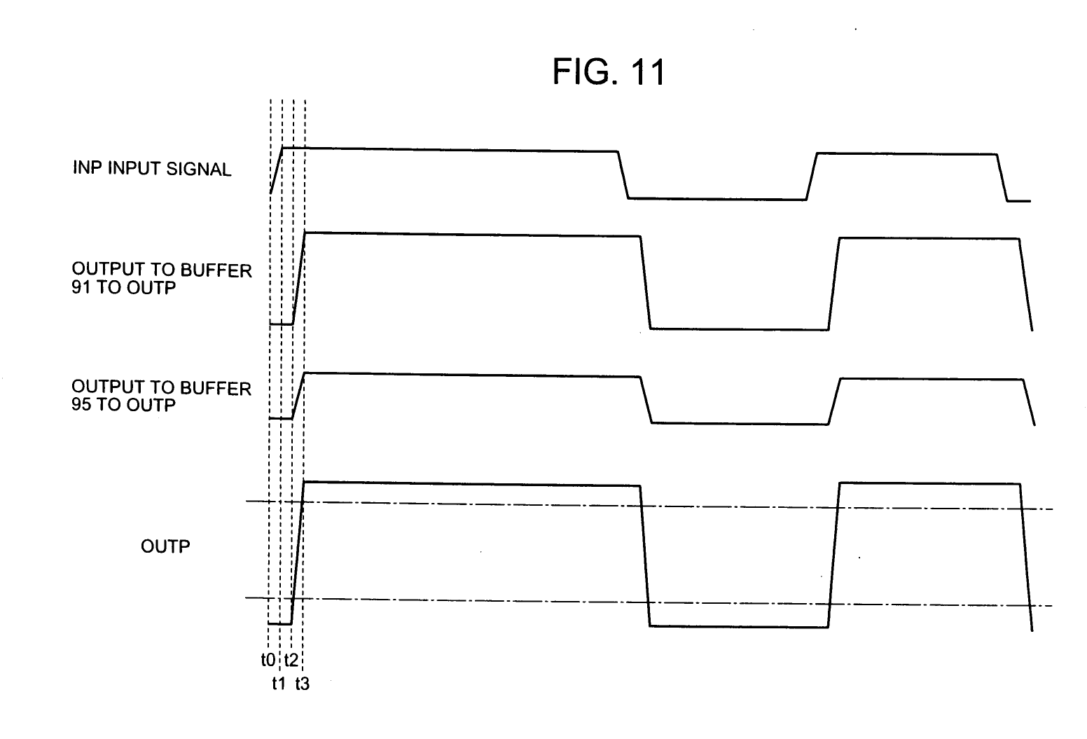

### DETAILED DESCRIPTION OF THE PREFERRED EMBODIMENTS

Hereinafter, embodiments of the present invention are described with reference to the attached drawings.

### Embodiment 1

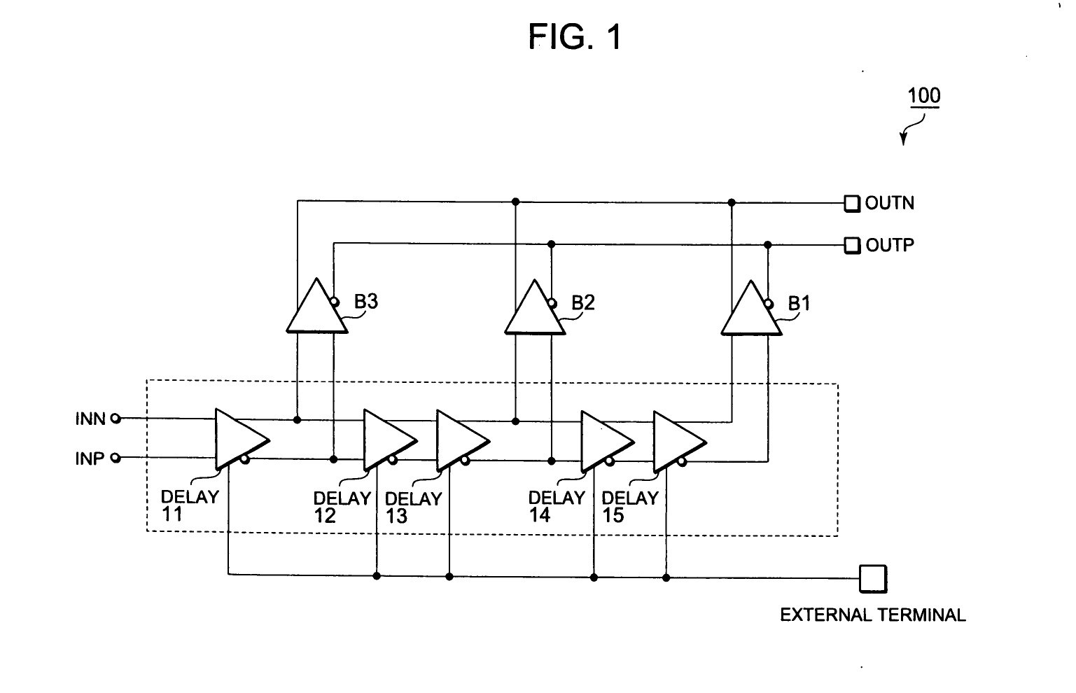

FIG. 1 is a block diagram showing an output buffer circuit 100 according to Embodiment 1 of the present invention. As shown in FIG. 1, the output buffer circuit 100 according to this embodiment includes a first output buffer (herein after referred to as output buffer B2), a second output buffer (herein after referred to as output buffer B1), and a third output buffer B3, a plurality of delay elements DELAY11, DELAY12, DELAY13, DELAY14, and DELAY15 corresponding to delay elements, differential input terminals (INP/INN), and differential output terminals (OUTP/OUTN). When a first delay path corresponds to the delay element DELAY11 in the plurality of delay elements DELAY11 to DELAY15, a second delay path corresponds to the delay elements DELAY12 and DELAY13. When the first delay path corresponds to the delay elements DELAY12 and DELAY13, the second delay path corresponds to the delay elements DELAY14 and DELAY15. Note that the differential input terminals (INP/INN) include the non-inverted input terminal INP and the inverted input terminal INN, and the differential output terminals (OUTP/OUTN) include the non-inverted output terminal OUTP and the inverted output terminal OUTN.

The delay elements DELAY11 to DELAY15 are coupled in series. The output buffer B2 receives input signals through at least one delay element. The output buffer B1 receives input signals through delay elements larger in number than those in the case of the output buffer B2. Hereinafter, respective sections of the output buffer circuit 100 are described in detail with reference to FIG. 1.

Input terminals of the delay element DELAY 11 are coupled to the differential input terminals (INP/INN) and output terminals thereof are coupled to input terminals of the output buffer B3 and input terminals of the delay element DELAY12. Output terminals of the delay element DELAY12 are coupled to input terminals of the delay element DELAY13. Output terminals of the delay element DELAY13 are coupled to input terminals of the output buffer B2 and input terminals of the delay element DELAY14. Output terminals of the delay element DELAY14 are coupled to input terminals of the delay element DELAY15. Output terminals of the delay element DELAY15 are coupled to input terminals of the output buffer B1. Output terminals of the output buffers B1 to B3 are coupled in common to the differential output terminals (OUTP/OUTN).

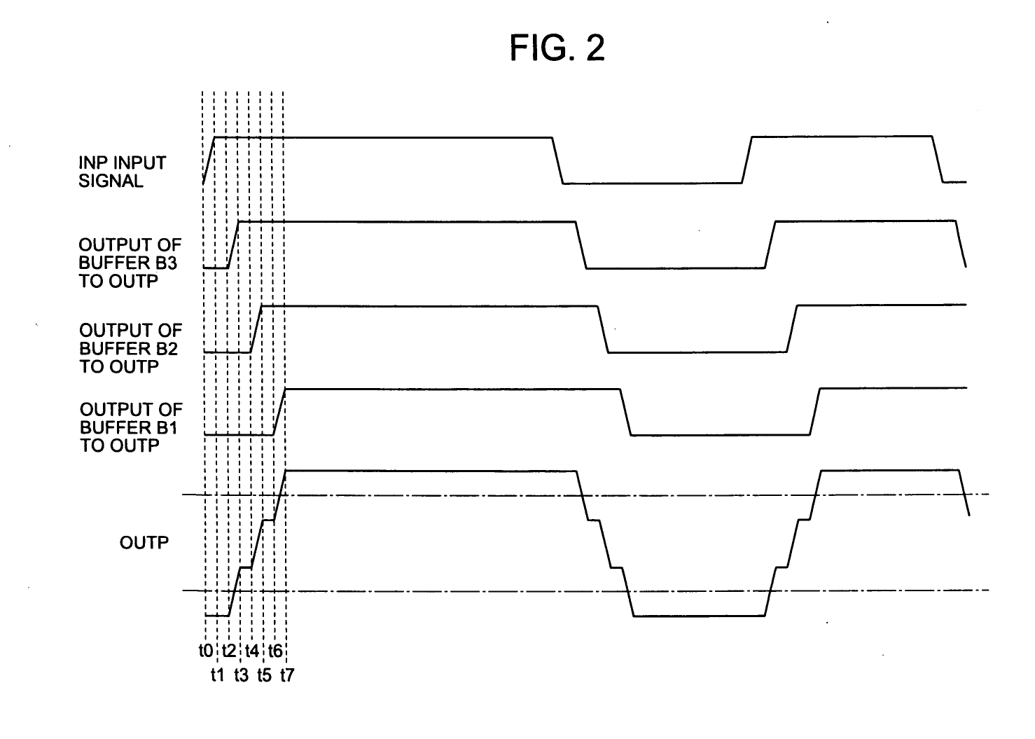

FIG. 2 is a timing chart showing waveforms at respective sections in the output buffer circuit 100 of FIG. 1. Hereinafter, the operation of the output buffer circuit 100 according to this embodiment is described in detail with reference to FIGS. 1 and 2. Assume that the respective delay elements DELAY11 to DELAY15 have the same delay time, and each of the output buffers B1 to B3 does not have a delay time and has the same drivabilities.

FIG. 2 shows the waveforms at the respective sections between the non-inverted input terminal INP of the differential input terminals (INP/INN) and the non-inverted output terminal OUTP of the differential output terminals (OUTP/OUTN). A data signal is inputted to the non-inverted input terminal INP (see the waveform “INP INPUT SIGNAL” of FIG. 2). The delay element DELAY11 delays the input data signal to output the delayed data signal. The signal outputted from the delay element DELAY11 is outputted to the non-inverted output terminal OUTP through the output buffer B3. That is, the output waveform of the output buffer B3 rises up with the total delay time (see t0 to t2 of FIG. 2) which occurs in the delay element DELAY11 relative to the data signal inputted to the non-inverted input terminal INP (see t2 and t3 of FIG. 2).

The delay element DELAY12 delays the signal outputted from the delay element DELAY11 to output the delayed signal. The delay element DELAY13 delays the signal outputted from the delay element DELAY12 to output the delayed signal. The signal outputted from the delay element DELAY13 is outputted to the non-inverted output terminal OUTP through the output buffer B2. That is, the output waveform of the output buffer B2 rises up with the total delay time (see t0 to t4 of FIG. 2) which occurs in the delay elements DELAY11 to DELAY13 relative to the data signal inputted to the non-inverted input terminal INP (see t4 and t5 of FIG. 2).

The delay element DELAY14 delays the signal outputted from the delay element DELAY13 to output the delayed signal. The delay element DELAY15 delays the signal outputted from the delay element DELAY14 to output the delayed signal. The signal outputted from the delay element DELAY15 is outputted to the non-inverted output terminal OUTP through the output buffer B1. That is, the output waveform of the output buffer B1 rises up with the total delay time (see t0 to t6 of FIG. 2) which occurs in the delay elements DELAY11 to DELAY15 relative to the data signal inputted to the non-inverted input terminal INP (see t6 and t7 of FIG. 2).

As described above, the signals outputted from the output buffers B1 to B3 are outputted to then on-inverted output terminal OUTP. An output signal OUTP shown in FIG. 2 becomes a composite signal of the signals outputted from the output buffers B1 to B3. That is, as shown in FIG. 2, in the output buffer circuit 100, the rising gradient of the output signal OUTP is set based on the total delay time of the delay elements DELAY14 and DELAY15.

As described above, according to this embodiment, the plurality of delay elements (DELAY11 to DELAY15) are coupled in series to reflect the delay time of the signal inputted to the output buffer B2 in the delay time of the signal inputted to the output buffer B1. That is, the delay time between the input signal of the output buffer B2 and the input signal of the output buffer B is a delay time (herein after referred to as delay time-A) determined by the delay elements coupled between the input terminals of the output buffer B2 and the input terminals of the output buffer B1. Therefore, the output signal of the output buffer B1 is constantly changed with the delay time-A relative to the output signal of the output buffer B2. The output buffer circuit 100 according to this embodiment outputs the composite signal of the output signal of the output buffer B2 and the output signal of the output buffer B1. Thus, the output buffer circuit 100 can set the rising and falling times of the composite signal based on the delay time-A.

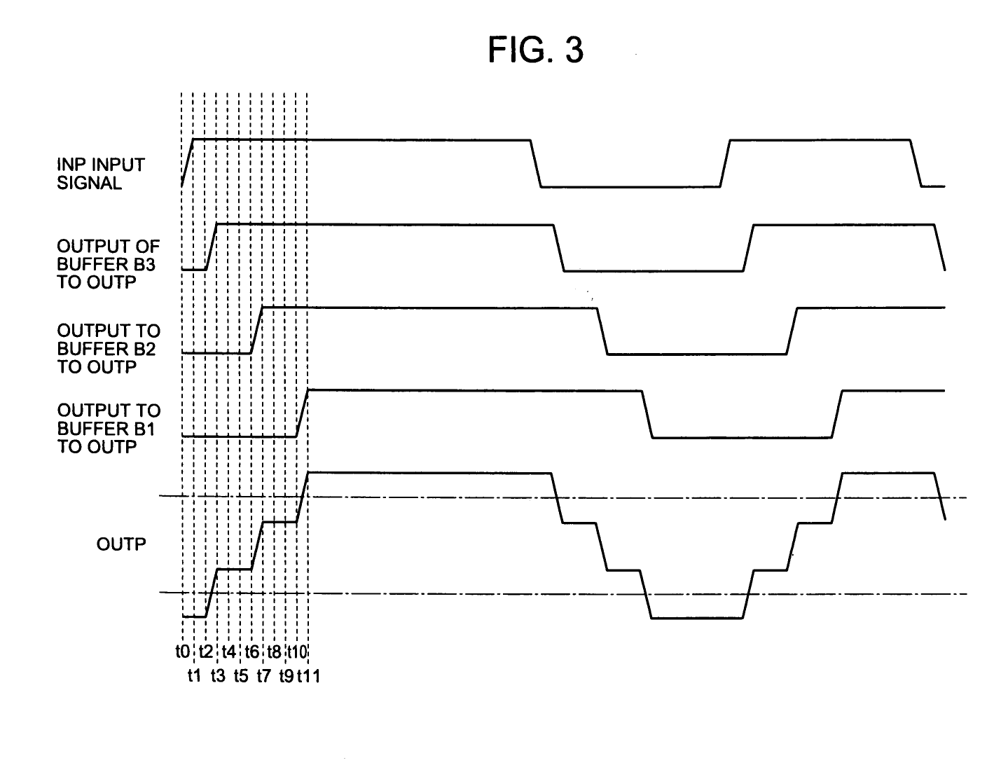

According to this embodiment, the delay elements DELAY11 to DELAY15 can adjust the delay amount. FIG. 3 shows waveforms at the respective sections in the case where the delay amount of the delay elements DELAY12 to DELAY15 is twice the delay amount shown in FIG. 2. In this case, the output waveform of the output buffer B2 rises up with the total delay time (see t0 to t6 of FIG. 3) which occurs in the delay elements DELAY11 to DELAY13 relative to the data signal inputted to the non-inverted input terminal INP (see t6 to t7 of FIG. 3). The output waveform of the output buffer B1 rises up with the total delay time (see t0 to t10 of FIG. 3) which occurs in the delay elements DELAY11 to DELAY15 relative to the data signal inputted to the non-inverted input terminal INP (see t10 and t11 of FIG. 3). That is, the output buffer circuit 100 can alter the rising and falling times of the output signal outputted from each of the differential output terminals (OUTP/OUTN). When the number of delay elements coupled in series is changed, the rising and falling times of the output signal can be altered.

The delay amount can be adjusted in response to a delay control signal generated in a chip. The delay elements DELAY11 to DELAY15 shown in FIG. 1 are coupled to an external terminal. In the output buffer circuit 100, when the delay control signal inputted to the external terminal is used, the delay amount of the delay elements DELAY11 to DELAY15 can be adjusted from the outside of the chip.

The conventional output buffer circuit has the structure in which the delay path for delaying the output signal of each of the output buffers is provided for each of the output buffers, so the delay times of the delay elements are varied by manufacturing variations in the delay elements. Therefore, in the case of the conventional output buffer circuit, the delay times of the delay elements coupled to the respective output buffers may be reversed to one another. On the other hand, in the case of the output buffer circuit 100 according to this embodiment, the signal is inputted to the output buffer B3 through the delay element DELAY11 and then the signal passing through the delay elements DELAY11 to DELAY13 is inputted to the output buffer B2. After the signal is inputted to the output buffer B2, the signal passing through the delay elements DELAY11 to DELAY15 is inputted to the output buffer B1. Therefore, the delay times of the delay elements coupled to the respective output buffers in the output buffer circuit 100 can be prevented from being reversed to one another.

When the plurality of output buffers are provided, the conventional output buffer circuit has the structure in which the delay path for delaying the output signal of each of the output buffers is provided for each of the output buffers. That is, the delay elements are coupled in parallel. Therefore, the circuit scale of the delay elements increases as the number of output buffers increases. On the other hand, in this embodiment, the plurality of delay elements are coupled in series, so a delay path coupled to a preceding-stage output buffer can be used as a part of a delay path coupled to a subsequent-stage output buffer. Thus, in the output buffer circuit 100, it is possible to suppress the increase in circuit scale of the delay elements, which is caused by the increase in the number of stages of the output buffers.

In this embodiment, the three stages of output buffers B1, B2, and B3 are provided to adjust the rising and falling times of the output signal. However, a plurality of stages of output buffers may be further provided.

### Embodiment 2

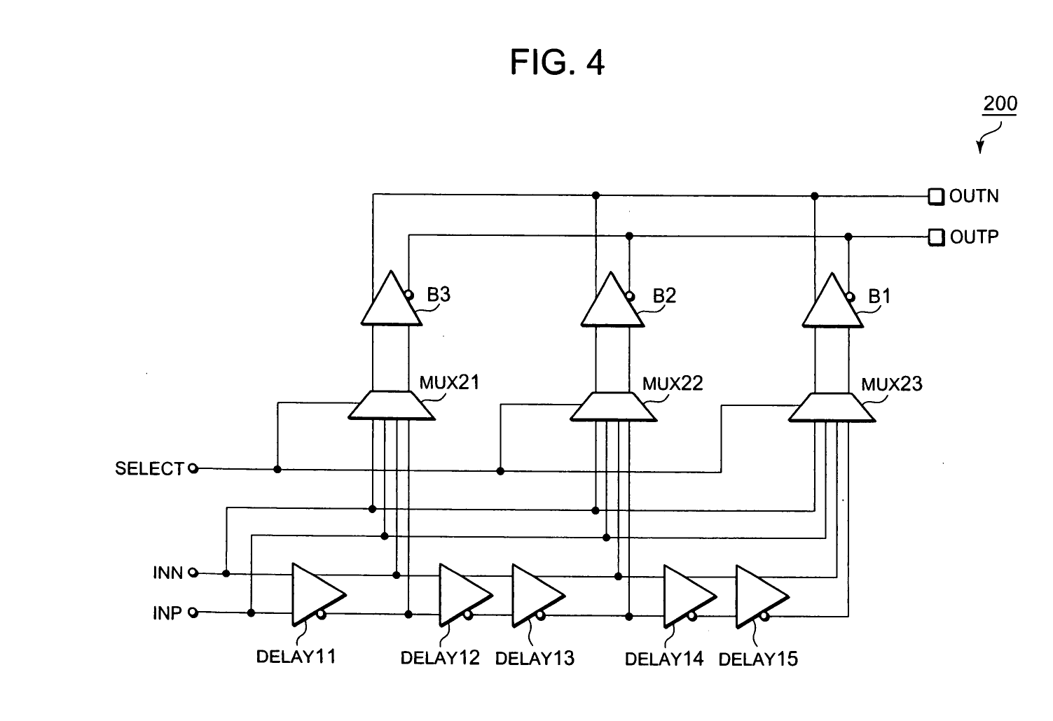

FIG. 4 shows an output buffer circuit 200 according to Embodiment 2 of the present invention. In FIG. 4, sections common to those of FIG. 1 are denoted by the same reference symbols and thus a detailed description thereof is omitted here. In the output buffer circuit 100 according to Embodiment 1, the signal for adjusting rising and falling times is outputted from each of the output buffers B1 to B3 provided between the delay elements coupled in series. The output buffer circuit 200 according to this embodiment has a structure in which multiplexing drivers MUX21, MUX22, and MUX23 are further provided to input in-phase data signals to the output buffers B1 to B3. Hereinafter, only the coupling relationship and operation of each of the multiplexing drivers MUX21, MUX22, and MUX23 are described.

Input terminals of the multiplexing driver MUX21 are coupled to the differential input terminals (INP/INN) and the output terminals of the delay element DELAY11. Output terminals of the multiplexing driver MUX21 are coupled to the input terminals of the output buffer B3. Input terminals of the multiplexing driver MUX22 are coupled to the differential input terminals (INP/INN) and the output terminals of the delay element DELAY13. Output terminals of the multiplexing driver MUX22 are coupled to the input terminals of the output buffer B2. Input terminals of the multiplexing driver MUX23 are coupled to the differential input terminals (INP/INN) and the output terminals of the delay element DELAY15. Output terminals of the multiplexing driver MUX23 are coupled to the input terminals of the output buffer B1. Each of the multiplexing drivers MUX21 to MUX23 is coupled to a select signal input terminal SELECT.

Each of the multiplexing drivers MUX21 to MUX23 selects one of the data signal inputted to the differential input terminal (INP/INN) and the data signal inputted through at least one corresponding delay path in response to the select signal input terminal SELECT and outputs the selected data signal to corresponding one of the output buffers B3, B2, and B1.

When each of the multiplexing drivers MUX21 to MUX23 selects the data signal inputted through the at least one corresponding delay path to output the selected data signal, the operation of the output buffer circuit 200 is identical to the operation of the output buffer circuit 100 according to Embodiment 1. Therefore, the operation in such a case is omitted here.

In contrast, when each of the multiplexing drivers MUX21 to MUX23 selects the data signal inputted to the differential input terminals (INP/INN) to output the selected data signal, the data signal is simultaneously inputted to the output buffers B3, B2, and B1. Therefore, the output waveform of the signal to be outputted to the differential output terminals (OUTP/OUTN) is a composite waveform of simultaneously changed outputs of the output buffers B3, B2, and B1. That is, a composite output waveform of the output buffer circuit 200 is not a step-like waveform as shown in FIG. 2 but a linearly changing waveform.

As described above, according to this embodiment, the in-phase input signal can be applied to the output buffers B3, B2, and B1. Therefore, the output buffer circuit 200 can generate a signal having a more rapid change than in the case of the output buffer circuit 100. That is, the output buffer circuit 200 can have a control range of each of the rising and falling times, which is wider than in the case of the output buffer circuit 100.

### Embodiment 3

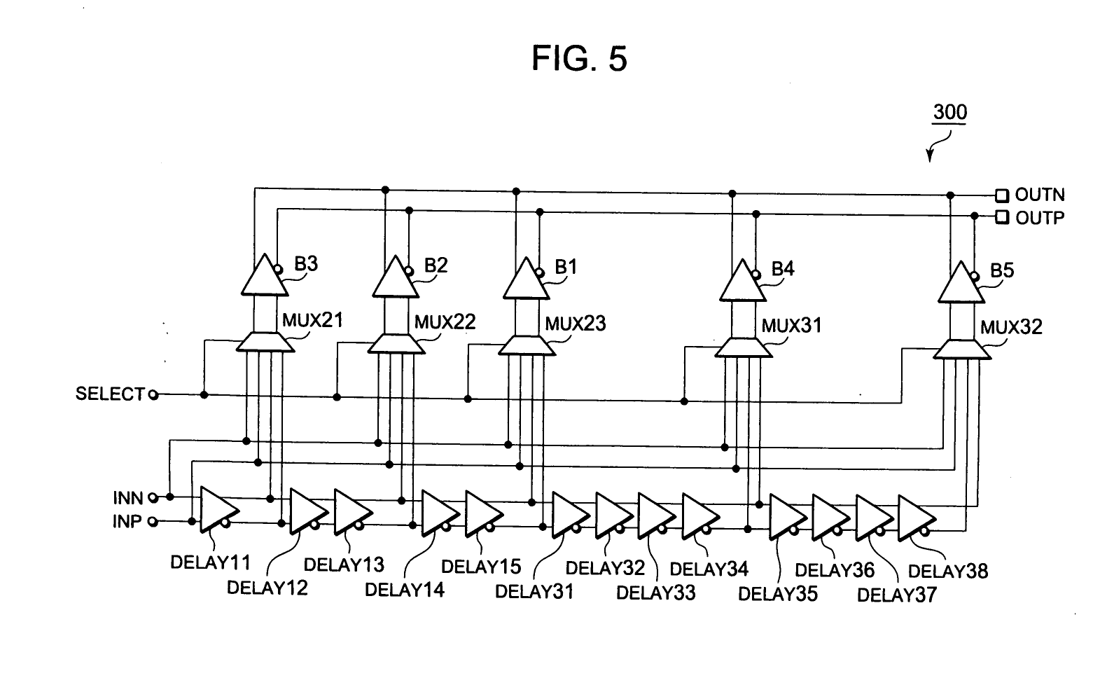

FIG. 5 shows an output buffer circuit 300 according to Embodiment 3 of the present invention. In FIG. 5, sections common to those of FIGS. 1 and 4 are denoted by the same reference symbols and thus a detailed description thereof is omitted here. In the output buffer circuit 300, a third output buffer (including, for example, output buffers B4 and B5), delay elements DELAY31, DELAY32, DELAY33, DELAY34, DELAY35, DELAY36, DELAY37, and DELAY38, and multiplexing drivers MUX31 and MUX32 are further provided at the subsequent stage of the output buffer circuit 200.

In the output buffer circuit 300, the delay elements DELAY31 to DELAY38 are coupled in series after the delay elements DELAY11 to DELAY15. Each of the delay elements DELAY11 to DELAY15 and each of the delay elements DELAY31 to DELAY38 have a non-inverted output terminal and an inverted output terminal, respectively. Each of the delay elements outputs a normal side signal of differential signals from the non-inverted output terminal and outputs an inverted side signal of the differential signals from the inverted output terminal.

Input terminals of the output buffer B4 are coupled to output terminals of the delay element DELAY34. Input terminals of the output buffer B5 are coupled to output terminals of the delay element DELAY38. Note that the delay elements coupled between the input terminals of the output buffer B1 and the input terminals of the output buffer B4 (for example, delay elements DELAY31 to DELAY34) operate as a third delay path. The multiplexing driver MUX31 is coupled between the input terminals of the output buffer B4 and the output terminals of the delay element DELAY34. Input terminals of the output buffer B5 are coupled to output terminals of the delay element DELAY38. The multiplexing driver MUX32 is coupled between the input terminals of the output buffer B5 and the output terminals of the delay element DELAY38. The operation of each of the multiplexing drivers MUX31 and MUX32 is substantially identical to the operation of each of the multiplexing drivers MUX21 to MUX23 and thus a description thereof is omitted here.

Each of the output buffers B1 to B3 outputs the signal to the inverted output terminal OUTN in response to the signal inputted to the inverted input terminal of corresponding one of the delay elements. Each of the output buffers B1 to B3 outputs the signal to the non-inverted output terminal OUTP in response to the signal outputted from the non-inverted input terminal of corresponding one of the delay elements. In contrast, each of the output buffers B4 and B5 outputs a signal to the inverted output terminal OUTN in response to a signal outputted from the non-inverted input terminal of corresponding one of the delay elements. Each of the output buffers B4 and B5 outputs a signal to the non-inverted output terminal OUTP in response to a signal inputted to the inverted input terminal of corresponding one of the delay elements. With such a structure, the outputs of the output buffers B4 and B5 are delayed and inverted relative to the outputs of the output buffers B1 to B3. In other words, when a coupling relationship between the third delay path and the output buffer coupled to the output terminals thereof is changed, the third delay path can transfer delayed and inverted input signals to the output buffer.

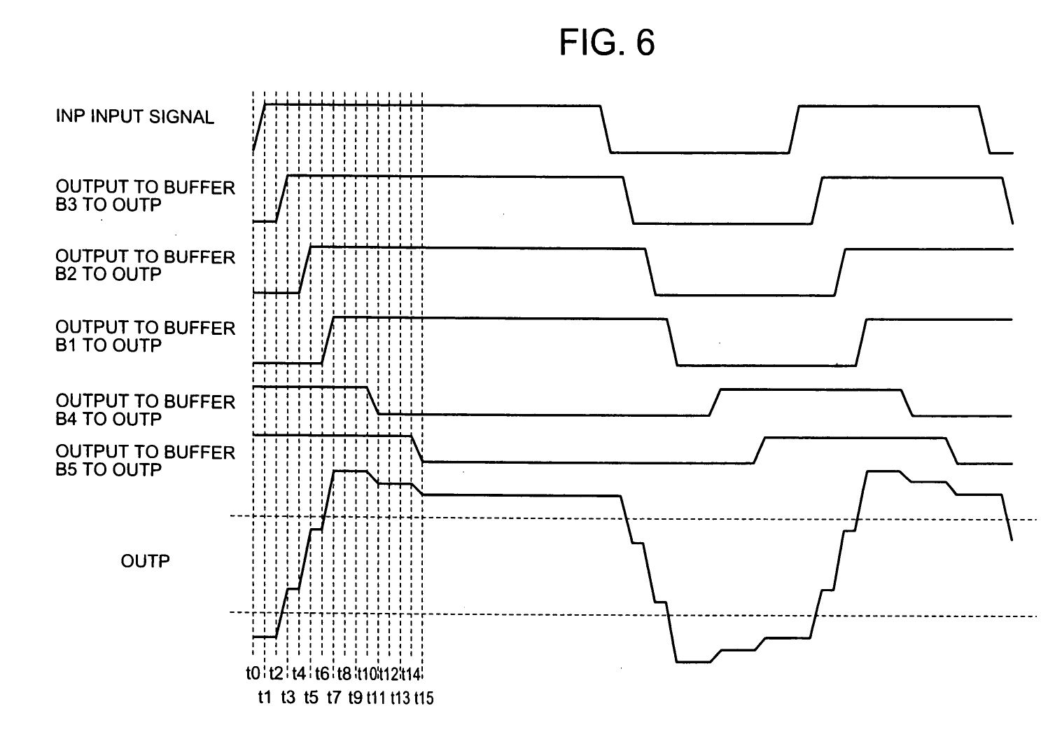

The operation of the output buffer circuit 300 is described with reference to a timing chart shown in FIG. 6. When an input signal from the non-inverted input terminal INP rises up (see t0 of FIG. 6), the rising of the input signal is delayed by the delay elements DELAY11 to DELAY15 and DELAY31 to DELAY38 and the input signal is serially transferred to the output buffers B1 to B5. The outputs of the output buffers B4 and B5 do not change at timings when the outputs of the output buffers B1 to B3 change, so the signal waveform at the non-inverted output terminal OUTP is the same as in the example shown in FIG. 2 (see t0 to t7 of FIG. 6).

After that, when the rising of the input signal reaches the output buffer B4, the output of the output buffer B4 falls down, so the signal waveform at the non-inverted output terminal OUTP also falls down (see t10 and t11 of FIG. 6). A delay time between a change in output of the output buffer B3 and a change in output of the output buffer B4 is a total delay time which occurs in the delay elements DELAY31 to DELAY34 (see t6 to t10 of FIG. 6). Then, when the rising of the input signal reaches the output buffer B5, the output of the output buffer B5 falls down, so the signal waveform at the non-inverted output terminal OUTP also falls down (see t14 and t15 of FIG. 6). A delay time between a change in output of the output buffer B4 and a change in output of the output buffer B5 is a total delay time which occurs in the delay elements DELAY35 to DELAY38 (see t10 to t14 of FIG. 6).

The output current drivabilities of the output buffers B4 and B5 are set lower than the output buffers B1 to B3. Therefore, when the outputs of the output buffers B4 and B5 change, a signal level of a changed output waveform slightly reduces. In other words, the output waveform is a waveform whose logically changed portion is emphasized.

As described above, according to this embodiment, the outputs of the subsequent-stage output buffers coupled through the plurality of delay elements in series are inverted relative to the outputs of the preceding-stage output buffers. Therefore, the output waveform can be subjected to emphasis processing.

In such a case, according to this embodiment, the subsequent-stage output buffers are coupled to the subsequent stage of the plurality of delay elements coupled to the preceding-stage output buffers through the delay elements coupled in series. Thus, the emphasized portion of the output waveform can be set to a suitable position relative to the rising and falling portions of the output waveform.

In this embodiment, the falling of the emphasized portion can be set in multiple stages. In the example shown in FIG. 6, two-stage falling is realized. When emphasis processing is to be performed with one-stage falling, it is necessary to lengthen a processing time of the portion subjected to the emphasis processing in order to improve the aperture of an eye pattern obtained from the output signal. However, when such an emphasis processing is completed, a latter half part of the portion subjected to the emphasis processing includes an excessively emphasized portion. Therefore, a waveform of the excessively emphasized portion is higher (or lower) in signal level than an original waveform. In contrast, according to this embodiment, when multiple-stage emphasis processing is performed, an emphasis effect of the excessively emphasized portion can be reduced. In other words, according to the output buffer circuit 300 in this embodiment, the waveform correction effect caused by the emphasis processing can be improved.

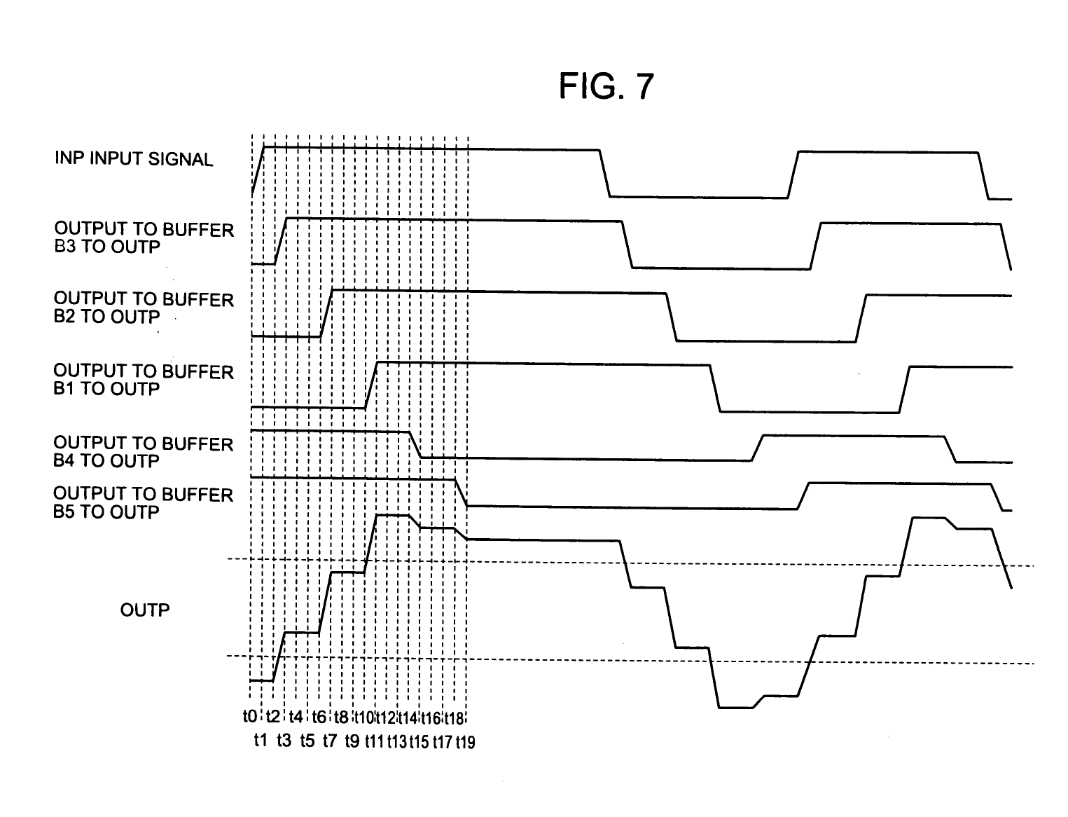

When the delay times of the plurality of delay elements are separately set, the output waveform can be arbitrarily set. For example, the delay times of the delay elements DELAY11 to DELAY15 are set to values larger than those in the example of FIG. 6 and the delay times of the delay elements DELAY31 to DELAY38 are set to values equal to those in the example of FIG. 6. When the delay times are set as described above, only the rising and the falling of the output signal can be delayed and the waveform of the portion emphasized by emphasis processing can be made equal to the waveform shown in FIG. 6. FIG. 7 is a timing chart of the output buffer circuit 300 at this time. In other words, according to the output buffer circuit 300 of this embodiment, the degree of freedom of waveform shaping can be improved as compared with the conventional output buffer circuits.

### Embodiment 4

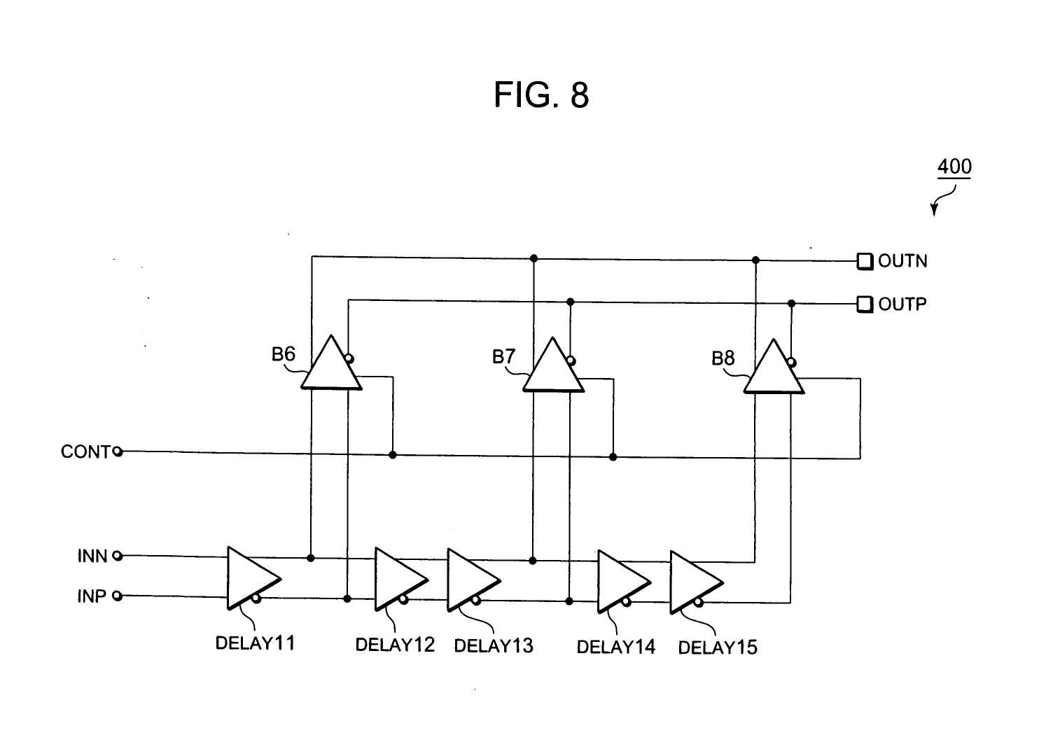

FIG. 8 shows an output buffer circuit 400 according to Embodiment 4 of the present invention. In FIG. 8, sections common to those of FIG. 1 are denoted by the same reference symbols and thus the detailed description thereof is omitted here. In the output buffer circuit 100 according to Embodiment 1, the output buffers B1 to B3 have the constant drivability. On the other hand, output buffers B6, B7, and B8 each having variable drivability are used instead of the output buffers B1 to B3 in the output buffer circuit 400 according to this embodiment.

A drivability control terminal CONT is coupled to each of the output buffers B6 to B8. The drivabilities of the output buffers B6 to B8 are determined in response to a drivability control signal inputted to the drivability control terminal CONT. When the drivabilities are increased, the rising and falling times can be advanced. When the drivabilities are reduced, the rising and the falling times can be delayed.

As described above, the output buffers B6 to B8 each having the variable drivability are provided in the output buffer circuit 400 according to this embodiment. The drivabilities of the output buffers B6 to B8 are determined in response to the drivability control signal inputted to the drivability control terminal CONT. Therefore, in the output buffer circuit 400, the drivabilities of the output buffers B6 to B8 can be controlled in response to the drivability control signal. That is, the rising and falling times can be adjusted by not only the change of the delay times using the delay elements but also the control of the drivabilities of the output buffers.

The present invention is not limited to the embodiments described above and thus modifications can be made as appropriate without departing from the spirit of the present invention. For example, the delay time between adjacent output buffers can be adjusted by changing the number of delay elements.

What is claimed is:

1. An output buffer circuit comprising:
an input terminal receiving an input signal;
a delay circuit coupled from said input terminal, said delay circuit having a plurality of delay elements to delay said input signal, said plurality of delay elements comprising:
a first delay path coupled to a first node, said first delay path performing time shifting transmission for said input signal, thereby extracting a first signal from said first node;
a second delay path coupled to a second node, said second delay path performing time shifting transmission longer than a delay time of said first delay path for said input signal, thereby extracting a second signal from said second node; and
a third delay path coupled to a third node, said third delay path performing time shifting transmission longer than a delay time of said second delay path for said input signal, thereby extracting a third signal from said third node;
an output terminal;
a first output buffer coupled from said first node to drive said output terminal in response to said first signal,
wherein a path of said first delay path and said first output buffer is arranged and configured to perform a logically NON reversible function in one pass through said first delay path and said first output buffer via said first node;
a second output buffer coupled from said second node to drive said output terminal in response to said second signal; and
a third output buffer coupled from said third node to drive said output terminal in response to said third signal,
wherein a path of said third delay path and said third output buffer is arranged and configured to perform a logically reversible function in one pass through said third delay path and said third output buffer via said third node.

2. The output buffer circuit according to claim 1,
wherein a path of said second delay path and said second output buffer is arranged and configured to perform a logically reversible function in one pass through said second delay path and said second output buffer via said second node.

3. The output buffer circuit according to claim 1,
wherein a path of said second delay path and said second output buffer is arranged and configured to perform a logically NON reversible function in one pass through said second delay path and said second output buffer via said second node.

4. The output buffer circuit according to claim 1,
wherein said delay circuit further comprises a delay control terminal receiving a delay control signal to alter a delay time of at least one of said plurality of delay elements in response to said delay control signal.

5. The output buffer circuit according to claim 1, further comprising:
a drivability control terminal receiving a drivability control signal to change drivability characteristics of at least one of said first output buffer, said second output buffer, and said third output buffer in response to said drivability control signal.

6. The output buffer circuit according to claim 1,
wherein said plurality of delay elements are coupled with each other in series.

7. An output buffer circuit comprising:
an input terminal receiving an input signal;
a delay circuit coupled from said input terminal, said delay circuit having a plurality of delay elements to delay said input signal, said plurality of delay elements comprising:
a first delay path coupled to a first node, said first delay path performing time shifting transmission for said input signal, thereby extracting a first signal from said first node;
a second delay path coupled to a second node, said second delay path performing time shifting transmission longer than a delay time of said first delay path for said input signal, thereby extracting a second signal from said second node; and
a third delay path coupled to a third node, said third delay path performing time shifting transmission longer than a delay time of said second delay path for said input signal, thereby extracting a third signal from said third node;
an output terminal;
a select terminal receiving a select signal;
a first multiplexing driver selectively coupled from one of said input terminal and said first node in response to said select signal to drive said output terminal in response to one of said input signal and said first signal, respectively,
wherein a path of said first delay path and said first multiplexing driver is arranged and configured to perform a logically NON reversible function in one pass through said first delay path and said first multiplexing driver via said first node, and a path of said input terminal and said first multiplexing driver is arranged and configured to perform a logically NON reversible function in one pass through said input terminal and said first multiplexing driver;
a second multiplexing driver selectively coupled from one of said input terminal and said second node in response to said select signal to drive said output terminal in response to one of said input signal and said second signal, respectively; and
a third multiplexing driver selectively coupled from one of said input terminal and said third node in response to said select signal to drive said output terminal in response to said one of input signal and said third signal, respectively,
wherein a path of said third delay path and said third multiplexing driver is arranged and configured to perform a logically reversible function in one pass through said third delay path and said third multiplexing driver via said third node, and a path of said input terminal and said third multiplexing driver is arranged and configured to perform a logically reversible function in one pass through said input terminal and said third multiplexing driver.

8. The output buffer circuit according to claim 7,
wherein a path of said second delay path and said second multiplexing driver is arranged and configured to perform a logically reversible function in one pass through said second delay path and said second multiplexing driver via said second node, and a path of said input terminal and said second multiplexing driver is arranged and configured to perform a logically reversible function in one pass through said input terminal and said second multiplexing driver.

9. The output buffer circuit according to claim 7,
wherein a path of said second delay path and said second multiplexing driver is arranged and configured to perform a logically NON reversible function in one pass through said second delay path and said second multiplexing driver via said second node, and a path of said input terminal and said second multiplexing driver is arranged and configured to perform a logically NON reversible function in one pass through said input terminal and said second multiplexing driver.

10. The output buffer circuit according to claim 7,
wherein said first multiplexing driver comprises:
a fourth node;
a first multiplexer selectively coupled from one of said input terminal and said first node in response to said select signal to drive said fourth node in response to one of said input signal and said first signal, respectively; and
a first output buffer coupled from said fourth node to drive said output terminal,
wherein said second multiplexing driver comprises:
a fifth node;
a second multiplexer selectively coupled from one of said input terminal and said second node in response to said select signal to drive said fifth node in response to one of said input signal and said second signal, respectively; and
a second output buffer coupled from said fifth node to drive said output terminal, and
wherein said third multiplexing driver comprises:
a sixth node;
a third multiplexer selectively coupled from one of said input terminal and said third node in response to said select signal to drive said sixth node in response to one of said input signal and said third signal, respectively; and
a third output buffer coupled from said sixth node to drive said output terminal.

11. The output buffer circuit according to claim 10,
wherein said delay circuit further comprises a delay control terminal receiving a delay control signal to alter a delay time of at least one of said plurality of delay elements in response to said delay control signal.

12. The output buffer circuit according to claim 10, further comprising:
a drivability control terminal receiving a drivability control signal to change drivability characteristics of at least one of said first output buffer, said second output buffer, and said third output buffer in response to said drivability control signal.

13. The output buffer circuit according to claim 7,
wherein said plurality of delay elements are coupled with each other in series.
